(19) United States
(12) Patent Application Publication
(10) Pub. No.: US 2026/0052728 A1
(43) Pub. Date: Feb. 19, 2026

(54) TRENCH MOSFET WITH REDUCED GATE CAPACITANCES

(71) Applicant: Microchip Technology Incorporated, Chandler, AZ (US)

(72) Inventors: Shesh Mani Pandey, Gilbert, AZ (US); Dennis Meyer, Chandler, AZ (US)

(73) Assignee: Microchip Technology Incorporated, Chandler, AZ (US)

(21) Appl. No.: 18/975,611

(22) Filed: Dec. 10, 2024

Related U.S. Application Data
(60) Provisional application No. 63/684,800, filed on Aug. 19, 2024.

(51) Int. Cl. H10D 30/66; H01L 21/265; H10D 30/01; H10D 62/10; H10D 62/17; H10D 62/832

(52) U.S. Cl. CPC H10D 30/668; H01L 21/26506; H10D 30/0297; H10D 62/124; H10D 62/393; H10D 62/8325

(57) ABSTRACT

A trench MOSFET with reduced gate capacitances, and a method of making the same. The reduction of the gate capacitances is achieved with asymmetric dielectric gate oxide on the sidewalls and bottom of the trench, with the gate oxide being thinner on the channel side and thicker on the opposite side and bottom. Silicon is implanted into a partial MOSFET structure, resulting in silicon-rich silicon carbide. A trench is asymmetrically etched into the implanted silicon, leaving a thicker layer of the implanted silicon on the second sidewall and bottom of the trench than on the first sidewall. A layer of silicon dioxide is grown over the first and second sidewalls and bottom of the trench, and the growing oxide converts the silicon-rich silicon carbide into additional silicon dioxide, resulting in a thicker layer of silicon dioxide at the second sidewall and bottom of the trench than at the first sidewall.

### RELATED APPLICATION

The present U.S. non-provisional patent application is related to and claims priority benefit of an earlier-filed U.S. provisional patent application titled “Trench MOSFET with Reduced Gate Capacitances,” Ser. No. 63/684,800, filed Aug. 19, 2024. The entire content of the identified earlier-filed application is incorporated by reference as if fully set forth herein.

### FIELD

The present disclosure relates to metal oxide semiconductor field-effect transistors and methods of making them, and more particularly, the various examples described herein concern a trench metal oxide semiconductor field-effect transistor with reduced gate capacitances, and a method of making a trench metal oxide semiconductor field-effect transistor with reduced gate capacitances.

### BACKGROUND

A metal-oxide-semiconductor field-effect transistor (MOSFET) is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, and choppers. It is generally desirable to improve the performance and reduce the cost of MOSFETs, but it can be difficult to do so.

This background discussion is intended to provide related information, and is not necessarily prior art.

### SUMMARY

Examples provide a trench MOSFET with reduced gate capacitances, and a method of making a trench MOSFET with reduced gate capacitances. Broadly, examples introduce an asymmetric dielectric gate oxide on the sidewalls and bottom of the trench, wherein the gate oxide on a first sidewall (nearer to the channel) is thinner than the gate oxide on a second sidewall (farther from the channel) and the bottom. This may be achieved by implanting a volume of silicon (Si), asymmetrically etching a trench into this volume, and then converting the remaining Si into an additional thickness of the silicon dioxide (SiO2) gate oxide. Examples advantageously provide a reduced gate-source capacitance (Vgs) and a reduced drain-source capacitance (Vds). The actual amount of reduction in these capacitances may depend on various factors, including the amount of additional thickness of the gate oxide, but one with ordinary skill in the art will appreciate that the capacitances of the examples described herein will be reduced relative to the capacitances of prior art devices.

In an example, a trench MOSFET with a reduced gate capacitance may include a volume of semiconductor material, a channel, a source, a drain, a body, a trench, and a gate. The channel may extend through the volume of semiconductor material and may include a first end and a second end. The source may be located at the first end of the channel, and the drain may be located at the second. The trench may extend into the volume of semiconductor material alongside the channel. The trench may include a first sidewall which is nearer to the channel, a second sidewall which is farther from the channel, and a bottom. The gate may be located within the trench. A dielectric material may be disposed between the gate and the trench, wherein a first average thickness of the dielectric material at the second sidewall and at the bottom of the trench is thicker than a second average thickness of the dielectric material at the first sidewall of the trench, resulting in a reduced gate capacitance at the second sidewall and at the bottom.

The preceding example may further include any one or more of the following features. The reduced gate capacitance may include a Vgs capacitance and a Vds capacitance. The semiconductor material may be an N-type epitaxial semiconductor material, the source may include an N+ material implanted into the N-type epitaxial semiconductor material, the drain may include an N+ material substrate, and the body may include a P+ material. The dielectric material may be SiO2. The first average thickness of the dielectric material at the second sidewall and bottom dielectric may be between one-and-one-half (1.5) to two (2) times thicker than the second average thickness of the dielectric material at the first sidewall of the trench. The trench MOSFET may further include a first electrical terminal coupled with the source, a second electrical terminal coupled with the drain, a third electrical terminal coupled with the gate, and a fourth electrical terminal coupled with the body for facilitating the application of appropriate voltages.

In another example, a method of making a trench MOSFET with a reduced gate capacitance may include the following operations. The method may begin with a partial MOSFET including a volume of semiconductor material; a channel through the volume of semiconductor material, the channel including a first end and a second end; a source located at the first end of the channel; a drain located at the second end; and a body. A volume of Si may be implanted into the semiconductor material, resulting in a Si-rich semiconductor material that overlaps the source and the body and extends alongside the channel. A trench may be asymmetrically etched into the Si-rich semiconductor material, with the trench including a first sidewall which is nearer to the channel, a second sidewall which is farther from the channel, and a bottom. The trench may be asymmetrical in that a first average thickness of the Si-rich semiconductor material remaining at the second sidewall and the bottom of the trench is thicker than a second average thickness of the Si-rich semiconductor material remaining at the first sidewall. A dielectric material may be deposited at the first sidewall, the second sidewall, and the bottom of the trench. The dielectric material may convert the Si-rich semiconductor material into additional dielectric material, such that a first total average thickness of the dielectric material at the second sidewall and at the bottom of the trench is thicker than a second total average thickness of the dielectric material at the first sidewall, resulting in a reduced gate capacitance at the second sidewall and at the bottom. A polysilicon material may be deposited in the trench to form a gate.

The preceding example may further include any one or more of the following features. The reduced gate capacitance may include a Vgs capacitance and a Vds capacitance. The semiconductor material may be an N-type epitaxial semiconductor material, the source may include an N+ material implanted into the N-type epitaxial semiconductor material, the drain may include an N+ material substrate, and the body may include a P+ material. The semiconductor material may be silicon carbide (SiC), the dielectric material may be SiO2, and the SiO2 may convert the Si-rich semiconductor material into additional SiO2. The first total thickness of dielectric material at the second sidewall and bottom of the trench may be between one-and-one-half (1.5) to two (2) times thicker than the second total thickness at the first sidewall of the trench. The method may further include adding a first electrical terminal to the source, adding a second electrical terminal to the drain, adding a third electrical terminal to the gate, and adding a fourth electrical terminal to the body to facilitate applying appropriate voltages.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a cross-sectional elevation block view of a first example of a trench MOSFET showing various internal capacitances;

FIG. 2 is a partial cross-sectional elevation schematic view of a second example of a trench MOSFET showing various internal capacitances;

FIG. 3 is a cross-sectional elevation view of an example of a trench MOSFET with reduced gate capacitances;

FIG. 4 is a flowchart of operations in an example of a method of making a trench MOSFET with reduced gate capacitances;

FIG. 5A is a cross-sectional elevation view of the result of an operation in the method of FIG. 4, wherein a partial MOSFET structure is shown;

FIG. 5B is a cross-sectional elevation view of the result of an operation in the method of FIG. 4, wherein silicon has been implanted into the partial structure;

FIG. 5C is a cross-sectional elevation view of the result of an operation in the method of FIG. 4, wherein a trench has been etched into the structure and into the implanted silicon;

FIG. 5D is a cross-sectional elevation view of the result of an operation in the method of FIG. 4, wherein a gate oxide has been provided on the bottom and sidewalls of the trench;

FIG. 5E is a cross-sectional elevation view of the result of an operation in the method of FIG. 4, wherein a polysilicon is deposited into the trench; and

FIG. 5F is a cross-sectional elevation view of the result of an operation in the method of FIG. 4, wherein electrical terminals are added.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Thus, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

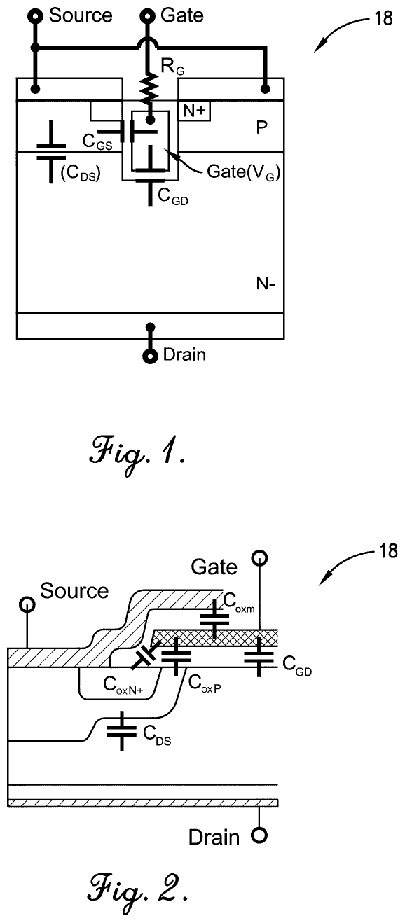

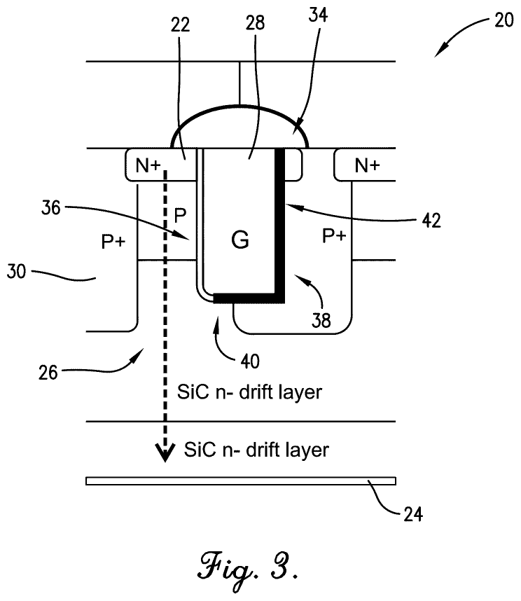

Referring to FIGS. 1 and 2, a cross-sectional elevation view of an example of a trench MOSFET 18 shows various internal capacitances. Ciss is an input capacitance, which is the sum of the gate-drain and gate-source capacitance (i.e., Ciss=Cgd+Cgs). Crss is a reverse transfer capacitance, which is the gate-drain capacitance (i.e., Crss=Cgd). Coss is an output capacitance, which is the sum of the gate-drain and drain-source capacitance (i.e., Coss=Cgd+Cds). For MOSFETs, a lower Ciss is desirable. Referring particularly to FIG. 2, Cgs results from the parallel connection of CoxN+, CoxP, and Coxm.

Examples provide a trench MOSFET with reduced gate capacitances, and a method of making a trench MOSFET with reduced gate capacitances. The reduction of the gate capacitances, which may include Cgs and Cds, is achieved with asymmetric dielectric gate oxide on the sidewalls and bottom of the trench, wherein the gate oxide on a first sidewall (which is the side of the trench nearer to the channel) is thinner than the gate oxide on a second sidewall (the opposite side which is father from the channel) and the bottom. Applications include Si and SiC devices. Broadly, Si may be implanted (using, e.g., an ion implanter) into a partial MOSFET structure, resulting in Si-rich SiC. A trench may be asymmetrically etched into the partial MOSFET structure, including into the implanted Si, leaving a thicker layer of the implanted Si on the second sidewall and bottom of the trench than on the first sidewall. A layer of SiO2 gate oxide may be grown over the first and second sidewalls and bottom of the trench, wherein the growing oxide may convert the Si in the Si-rich SiC into additional SiO2, resulting in a thicker SiO2 layer at the second sidewall and bottom of the trench. Polysilicon may be deposited into the trench to form a gate. The second sidewall and bottom layer of SiO2 may be approximately between one-and-one-half (1.5) and two (2) times thicker than that of the SiO2 on the first sidewall. Thus, if the SiO2 layer on the first sidewall is four hundred (400) Angstroms thick, then the SiO2 layer on the second sidewall and bottom may be approximately between six hundred (600) and eight hundred (800) Angstroms thick.

It should be noted that “thickness” as used herein may refer to maximum or minimum thickness along a segment (e.g., first and second sidewalls and bottom), or average thickness.

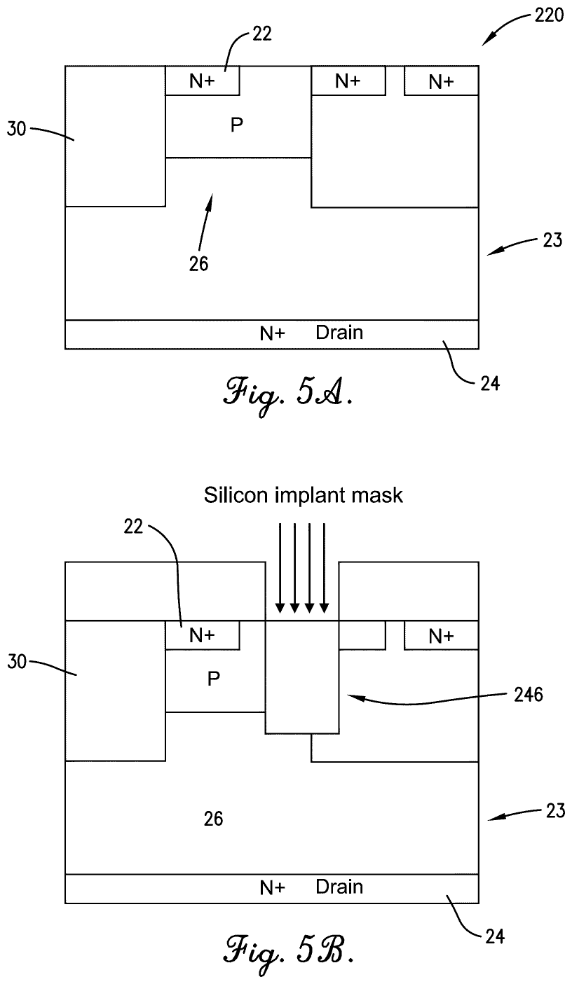

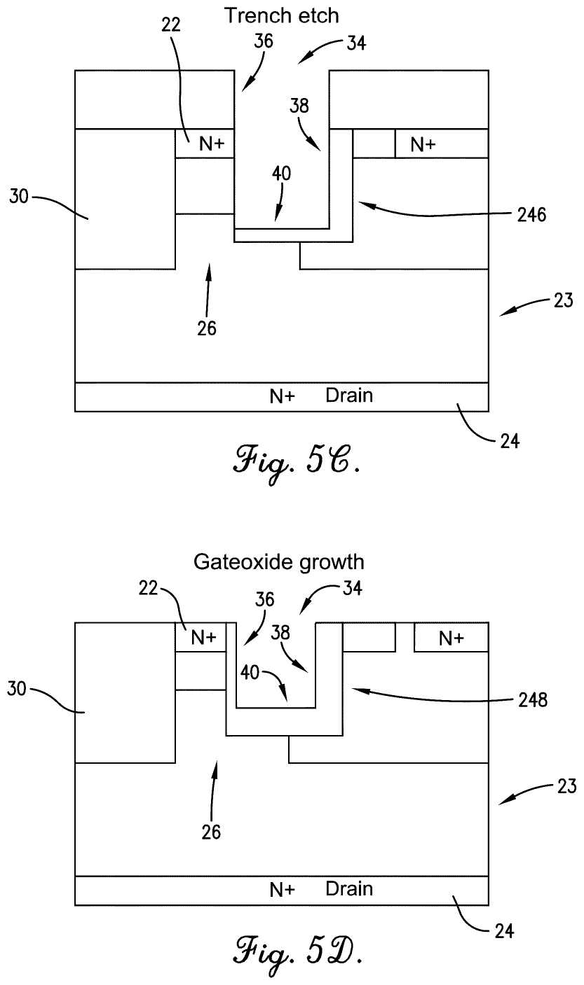

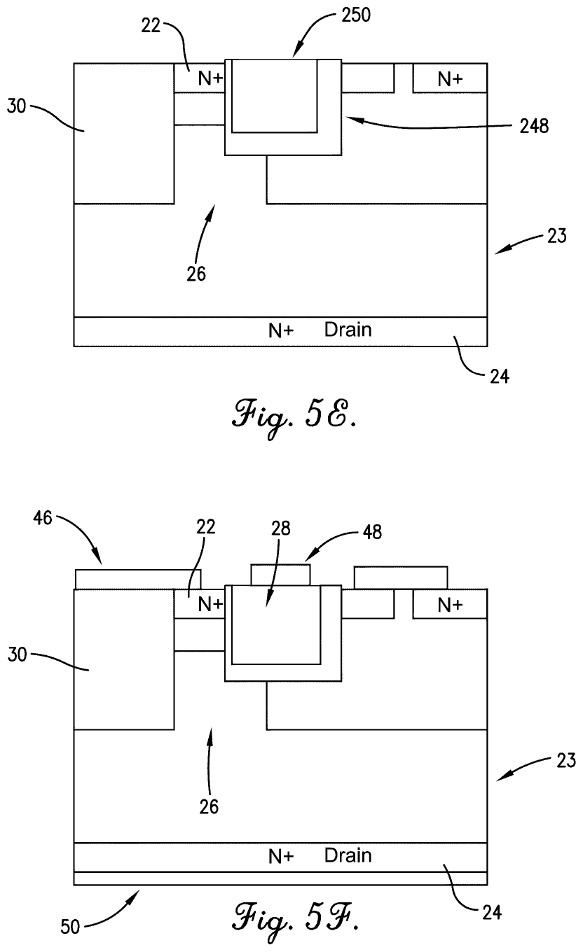

Referring to FIG. 3, an example of a trench MOSFET 20 with reduced gate capacitances may include a source 22, a drain 24, a channel 26, a gate 28, and a body 30. The source 22 may provide an entrance for majority charge carriers (in this case, electrons) into the channel 26. The source 22 may be constructed from or include N+ material located at a first end of a volume of N-type epitaxial semiconductor material (e.g., SiC) 23 (seen labeled in FIGS. 5A-F). The drain 24 may provide an exit for the majority charge carriers from the channel 26. The drain 24 may be constructed from or include N+ material located on a second end of the semiconductor material 23 which is opposite and spaced apart from the source 22. The channel 26 may be a region of the semiconductor material 23 between the source 22 and the drain 24 and through which the majority charge carriers move, i.e., through which electrical current flows. The gate 28 may facilitate control over the flow of charge carriers through the channel 26. The gate 28 may be constructed from or include polysilicon material. The body (or substrate) 30 may cooperate with the gate 28 to control current flow between the source 22 and the drain 24. The body 30 may include or be constructed from P+ material.

The gate 28 may be located in a trench 34 which is etched or otherwise created into the semiconductor material 23 alongside the channel 26. The trench 34 may include first and second sidewalls 36, 38 and a bottom 40. The first sidewall 36 may be proximate or nearer to the channel 26, and the second sidewall 38 may be on the opposite side of the trench 34, which is farther from the channel 26. A dielectric material 42, or gate oxide, such as SiO2, may be provided at the first and second sidewalls 36, 38 and at the bottom 40 so as to be arranged partially around and electrically insulate the gate 28. The dielectric material 42 at the second sidewall 38 and at the bottom 40 may be thicker than the dielectric material 42 at the first sidewall 36. In one or more examples, the dielectric material 42 of the second sidewall 38 and bottom 40 of the trench 34 may be between one-and-one-half (1.5) to two (2) times thicker than that of the first sidewall 36.

Achieving a thicker dielectric at the second sidewall 38 and bottom 40 may be accomplished by implanting Si (using, e.g., an ion implanter) into a partial MOSFET structure, resulting in Si-rich SiC. The trench 34 may be asymmetrically etched into the partial MOSFET structure, including into the implanted Si, leaving a thicker layer of the implanted Si on the second sidewall 38 and bottom 40 of the trench 34 than on the first sidewall 36. A layer of SiO2 gate oxide may be grown over the first and second sidewalls 36, 38 and bottom 40 of the trench 34, wherein the growing oxide may convert the Si in the Si-rich SiC to additional SiO2, resulting in a thicker SiO2 layer at the second sidewall 38 and bottom 40 than at the first sidewall 36. Polysilicon may then be deposited into the trench 34 to form the gate 28. The result is a reduction of the gate capacitances, Cgs and Cds. The actual amount of reduction in these capacitances may depend on various factors, including the amount of additional thickness of the gate oxide, but one with ordinary skill in the art will appreciate that the capacitances of the examples described herein will be reduced relative to the capacitances of prior art devices.

In operation, when a voltage, Vgs, is applied between the source 22 and the gate 28, the generated electric field penetrates through the dielectric layer at the first sidewall 36 of the trench 34 and creates an inversion layer or channel at the semiconductor-insulator interface. The inversion layer provides the channel 26 through which electrical current can pass between the source 22 and drain 24 terminals. Varying the voltage, Vgb, between the gate 28 and the body 30 modulates the conductivity of this layer and thereby controls the electrical current, Id, flowing between the source 22 and the drain 24.

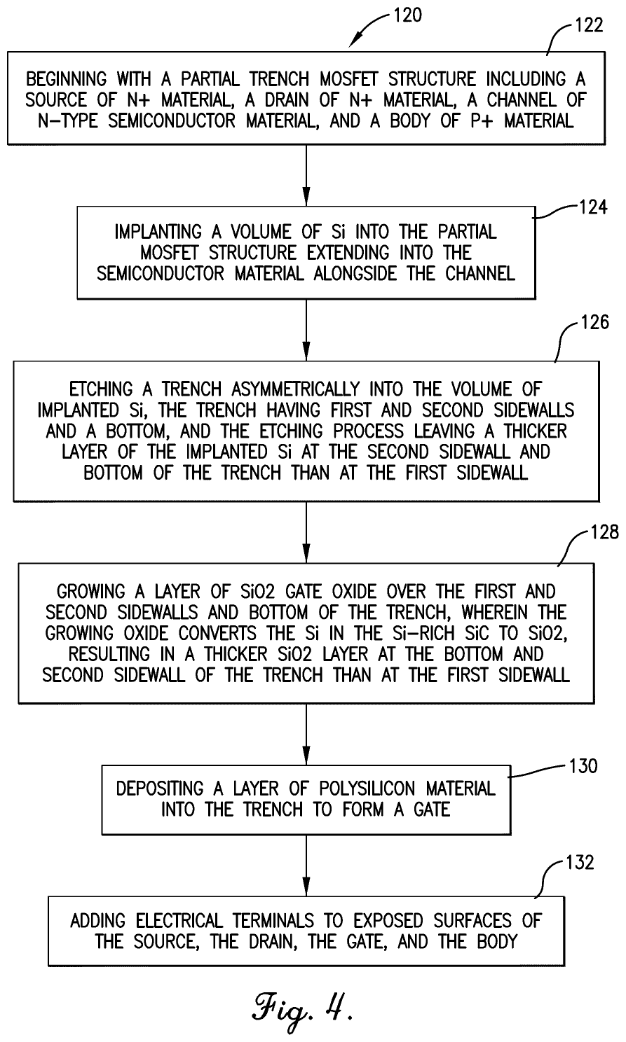

Referring to FIG. 4, an example of a method 120 of manufacturing a trench MOSFET with reduced gate capacitances may include the operations set forth below. Referring additionally to FIGS. 5A-D, example results of the operations of the method 120 are shown. The method may begin with a partial trench MOSFET structure 220 including a source 22 of N+ material, a volume of N-type epitaxial semiconductor material 23, a drain 24 of N+ material, a channel 26, and a body 30 of P+ material, as shown in 122 and seen in FIG. 5A.

A volume 246 of Si may be implanted (using, e.g., an ion implanter) into the partial MOSFET structure 220 extending into the semiconductor material 23 alongside the channel 26, resulting in Si-rich SiC, as shown in 124 and seen in FIG. 5B. A trench 34, which may ultimately receive the gate 28, may be asymmetrically etched into the volume 246 of implanted Si, wherein the trench 34 includes first and second sidewalls 36, 38 and a bottom 40, and the etching process leaves a thicker layer of the implanted Si at the second sidewall 38 and bottom 40 of the trench 34 than at the first sidewall 36, as shown in 126 and seen in FIG. 5C.

A layer of SiO2 gate oxide 248 may be grown or otherwise provided over the first and second sidewalls 36, 38 and bottom 40 of the trench 34, and the growing oxide may convert the remaining implanted Si in the Si-rich SiC to SiO2, resulting in a total thickness of the SiO2 layer at the second sidewall 38 and bottom 40 of the trench 34 being thicker than a total thickness of the SiO2 at the first sidewall 36, as shown in 128 and seen in FIG. 5D. A layer of polysilicon material 250, which may form the gate 28, may be deposited into the trench 34, such that the SiO2 gate oxide at the sides and bottom of the trench 34 is arranged partially around and electrically insulates the gate 28, as shown in 130 and seen in FIG. 5E. The result is a reduction of the gate capacitances, Cgs and Cds. Electrical terminals 46, 48, 50 may be added to respective exposed surfaces of the source 22 and body 30, the drain 24, and the gate 28, as shown in 132 and seen in FIG. 5F, to facilitate the application of appropriate electrical voltages. Additional processing may occur as desired.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

1. A trench metal oxide semiconductor field-effect transistor with a reduced gate capacitance, the trench metal oxide semiconductor field-effect transistor comprising:
a volume of semiconductor material;
a channel through the volume of semiconductor material, the channel including a first end and a second end;
a source located at the first end of the channel;
a drain located at the second end of the channel;
a body;
a trench extending into the volume of semiconductor material alongside the channel, the trench including a first sidewall which is nearer to the channel, a second sidewall which is farther from the channel, and a bottom;
a gate located within the trench; and
a dielectric material between the gate and the trench, wherein a first average thickness of the dielectric material along the second sidewall and the bottom of the trench is thicker than a second average thickness of the dielectric material along the first sidewall of the trench.

2. The trench metal oxide semiconductor field-effect transistor of claim 1, wherein the dielectric material results in a reduced gate capacitance relative to an otherwise identical transistor having the semiconductor material in place of the dielectric material, the reduced gate capacitance including a gate-source capacitance and a drain-source capacitance.

3. The trench metal oxide semiconductor field-effect transistor of claim 1, wherein
the semiconductor material is an N-type epitaxial semiconductor material;
the source includes an N+ material implanted into the N-type epitaxial semiconductor material;
the drain includes an N+ material substrate; and
the body includes a P+ material.

4. The trench metal oxide semiconductor field-effect transistor of claim 1, wherein the dielectric material is silicon dioxide.

5. The trench metal oxide semiconductor field-effect transistor of claim 1, wherein the first average thickness of the dielectric material along the second sidewall and bottom dielectric is between one-and-one-half (1.5) to two (2) times thicker than the second average thickness of the dielectric material along the first sidewall of the trench.

6. The trench metal oxide semiconductor field-effect transistor of claim 1, further including a first electrical terminal coupled with the source, a second electrical terminal coupled with the drain, a third electrical terminal coupled with the gate, and a fourth electrical terminal coupled with the body.

7. A method of making a trench metal oxide semiconductor field-effect transistor with a reduced gate capacitance, beginning with a volume of semiconductor material, a channel through the volume of semiconductor material, the channel including a first end and a second end, a source located at the first end of the channel, a drain located at the second end of the channel, and a body, the method comprising:
implanting a volume of silicon into the semiconductor material, resulting in a silicon-rich semiconductor material that extends alongside the channel;
etching a trench asymmetrically into the silicon-rich semiconductor material, the trench including a first sidewall which is nearer to the channel, a second sidewall which is farther from the channel, and a bottom, wherein the trench is asymmetrical in that a first average thickness of the silicon-rich semiconductor material remaining along the second sidewall and the bottom of the trench is thicker than a second average thickness of the silicon-rich semiconductor material remaining along the first sidewall;
depositing a dielectric material at the first sidewall, the second sidewall, and the bottom of the trench, wherein the dielectric material converts the silicon-rich semiconductor material into additional dielectric material, and wherein a first total average thickness of the dielectric material along the second sidewall and the bottom of the trench is thicker than a second total average thickness of the dielectric material along the first sidewall; and
depositing a polysilicon material in the trench to form a gate.

8. The method of claim 7, wherein the dielectric material results in a reduced gate capacitance relative to an otherwise identical transistor having the semiconductor material in place of the dielectric material, the reduced gate capacitance including a gate-source capacitance and a drain-source capacitance.

9. The method of claim 7, wherein
the semiconductor material is an N-type epitaxial semiconductor material;
the source includes an N+ material implanted into the N-type epitaxial semiconductor material;
the drain includes an N+ material substrate; and
the body includes a P+ material.

10. The method of claim 7, wherein the semiconductor material is silicon carbide, the dielectric material is silicon dioxide, and the silicon dioxide converts the silicon-rich semiconductor material into additional silicon dioxide.

11. The method of claim 7, wherein the first total average thickness of dielectric material along the second sidewall and bottom of the trench is between one-and-one-half (1.5) to two (2) times thicker than the second total average thickness along the first sidewall of the trench.

12. The method of claim 7, further including adding a first electrical terminal to the source, adding a second electrical terminal to the drain, adding a third electrical terminal to the gate, and adding a fourth electrical terminal to the body.

13. A method of making a trench metal oxide semiconductor field-effect transistor with a reduced gate capacitance, beginning with a volume of N-type epitaxial silicon carbide semiconductor material, a channel through the volume of N-type epitaxial semiconductor material, the channel including a first end and a second end, a source including an N+ material located at the first end of the channel, a drain including an N+ material substrate located at the second end of the channel, and a body including a P+ material, the method comprising:
implanting a volume of silicon into the N-type epitaxial semiconductor material, resulting in a silicon-rich silicon carbide semiconductor material that extends alongside the channel;
etching a trench asymmetrically into the silicon-rich silicon carbide semiconductor material, the trench including a first sidewall which is nearer to the channel, a second sidewall which is farther from the body, and a bottom, wherein the trench is asymmetrical in that a first average thickness of the silicon-rich silicon carbide semiconductor material remaining along the second sidewall and the bottom of the trench is thicker than a second average thickness of the silicon-rich silicon carbide semiconductor material remaining along the first sidewall;
depositing a silicon dioxide dielectric material at the first sidewall, the second sidewall, and the bottom of the trench, wherein the silicon dioxide dielectric material converts the silicon-rich silicon carbide semiconductor material into additional silicon dioxide dielectric material, and wherein a first total average thickness of the silicon dioxide dielectric material along the second sidewall and the bottom of the trench is thicker than a second total average thickness of the silicon dioxide dielectric material along the first sidewall; and
depositing a polysilicon material in the trench to form a gate.

14. The method of claim 13, wherein the dielectric material results in a reduced gate capacitance relative to an otherwise identical transistor having the semiconductor material in place of the dielectric material, the reduced gate capacitance including a gate-source capacitance and a drain-source capacitance.

15. The method of claim 13, wherein the first total average thickness of dielectric material along the second sidewall and bottom of the trench is between one-and-one-half (1.5) to two (2) times thicker than the second total average thickness along the first sidewall of the trench.

16. The method of claim 13, further adding a first electrical terminal to the source, adding a second electrical terminal to the drain, adding a third electrical terminal to the gate, and adding a fourth electrical terminal to the body.
